(19) United States
(12) Patent Application Publication
(10) Pub. No.: US 2020/0221608 A1
(43) Pub. Date: Jul. 9, 2020

(54) HEAT-DISSIPATING STRUCTURE AND METHOD FOR MANUFACTURING THE SAME

(71) Applicant: CATCHER TECHNOLOGY CO., LTD., TAINAN CITY (TW)

(72) Inventors: CHIA-HUNG CHANG, HSINCHU CITY (TW); SHIH-WEI LEE, TAINAN CITY (TW); HAN-CHOU LIAO, YUNLIN COUNTY (TW)

(21) Appl. No.: 16/428,148

(22) Filed: May 31, 2019

(30) Foreign Application Priority Data
Jan. 9, 2019 (TW) 108100857

(51) Int. Cl. H05K 7/20; D01D 5/00; F28F 21/08

(52) U.S. Cl. CPC H05K 7/20481; B32B 7/027; F28F 21/089; D01D 5/0007

(57) ABSTRACT

A heat-dissipating structure includes a plurality of heat-dissipating layers and at least one heat-buffering layer. The heat-dissipating layers are stacked together. Each of the heat-dissipating layers is formed by a thermally conductive metal coated polymer fiber or thermally conductive metal fiber. The at least one heat-buffering layer is disposed between the heat-dissipating layers.

### CROSS-REFERENCE TO RELATED PATENT APPLICATION

This application claims the benefit of priority to Taiwan Patent Application No. 108100857, filed on Jan. 9, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heat-dissipating structure, and more particularly to a polymer fiber based heat-dissipating structure and a method for manufacturing the same.

### BACKGROUND OF THE DISCLOSURE

With the design of electronic products towards the trend of light weight, thin profile and high performance, the electronic components required are forced to be reduced in size so that power density is greatly increased, causing an excessively high temperature. Therefore, how to thermally manage an electronic component in a limited internal space, i.e., use a heat-dissipating structure to remove heat generated from the electronic component in operation, becomes one of the problems to be solved in the related art.

For thermal management, a heat-dissipating structure can directly contact the electronic component or be spaced apart from the electronic component. For example, a graphite, metal or graphite/metal cooling sheet can be directly adhered to a high-power electronic component (e.g., processor) or to an adjacent parts (e.g., back cover), so as to remove heat from the electronic component. In addition, a high-power electronic component such as an LED can be disposed on a heat pipe. Accordingly, the heat generated from the electronic component can be transmitted to a heat-dissipating structure such as a heat sink and then be outwardly dissipated from the heat-dissipating structure.

Although said cooling sheet can cool the operated electronic component in time, its heat-dissipating ability still has some room for improvement and it is unfavorable to the light weight design. In addition, the heat pipe has a higher cost and, for heat dissipation, needs to work an additional heat-dissipating structure.

### SUMMARY OF THE DISCLOSURE

In response to the above-referenced technical inadequacies, the present disclosure provides a heat-dissipating structure, which can balance light weight, structural strength and heat-dissipating ability, and a method for manufacturing the same.

In one aspect, the present disclosure provides a method for manufacturing a heat-dissipating structure including the following steps. The first step is providing a composite polymer fiber and forming the composite polymer fiber into a layered structure. The composite polymer fiber has a thermally conductive metal precursor uniformly distributed thereon. The next step is reducing the thermally conductive metal precursor to thermally conductive metal so as to form the layered structure into a heat-dissipating layer. The next step is providing an organic polymer fiber and forming the organic polymer fiber into a heat-buffering layer. Finally, the above two or three steps can be repeated.

In one aspect, the present disclosure provides a heat-dissipating structure including a plurality of heat-dissipating layers and at least one heat-buffering layer. The heat-dissipating layers are stacked together. Each of the heat-dissipating layers is formed by a thermally conductive metal coated polymer fiber. The at least one heat-buffering layer is disposed between the heat-dissipating layers.

In one aspect, the present disclosure provides a heat-dissipating structure including a plurality of heat-dissipating layers and at least one heat-buffering layer. The heat-dissipating layers are stacked together. Each of the heat-dissipating layers is formed by a thermally conductive metal fiber. The at least one heat-buffering layer is disposed between the heat-dissipating layers.

One of the advantages of the present disclosure is that, in the heat-dissipating structure, the at least one heat-buffering layer is disposed between the heat-dissipating layers and each of the heat-dissipating layers is formed by a thermally conductive metal coated polymer fiber or thermally conductive metal fiber, so that heat from an electronic product which easily generates a large amount of heat can be removed. The heat-dissipating structure can transmit the heat generated from the electronic component in the horizontal direction (i.e., X-Y direction) via the heat-buffering layer and subsequently dissipate the heat over a large area via the heat-dissipating layers.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of a heat-dissipating structure according to first and second embodiments of the present disclosure.

FIG. 2 is an enlarged view of part II of FIG. 1.

FIG. 3 is an enlarged view of part III of FIG. 1.

FIG. 4 is a schematic view showing a portion of a thermally conductive metal coated polymer fiber as shown in FIG. 2.

FIG. 5 is another schematic view of the heat-dissipating structure according to the first and second embodiments of the present disclosure.

FIG. 6 is a schematic view showing a manufacturing process of a heat-dissipating layer of the heat-dissipating structure according to the first and second embodiments of the present disclosure.

FIG. 7 is a schematic view showing a portion of a composite polymer fiber as shown in FIG. 6.

FIG. 8 is a schematic view showing another manufacturing process of the heat-dissipating layer of the heat-dissipating structure according to the first and second embodiments of the present disclosure.

FIG. 9 is a schematic view showing a manufacturing process of a heat-buffering layer of the heat-dissipating structure according to the first and second embodiments of the present disclosure.

FIG. 10 is a schematic view showing an application of the heat-dissipating structure according to the first and second embodiments of the present disclosure.

FIG. 11 is a schematic view showing heat transmission paths of the heat-buffering layer of the heat-dissipating structure according to the first and second embodiments of the present disclosure.

FIG. 12 is an enlarged view of part XII of FIG. 1.

FIG. 13 is another schematic view showing a portion of the composite polymer fiber as shown in FIG. 6.

FIG. 14 is a schematic view of the heat-dissipating structure according to a third embodiment of the present disclosure.

FIG. 15 is a schematic view showing a manufacturing process of the heat-dissipating layer of the heat-dissipating structure according to the third embodiment of the present disclosure.

FIG. 16 is a graph showing temperature changes in a heat transmission test.

### DETAILED DESCRIPTION OF THE EXEMPLARY EMBODIMENTS

In recent years, there are urgent needs for heat management materials and their related techniques due to the miniaturization requirement of the electronic component and the increases in the power requirement. The handheld electronic system such as a smart phone, tablet or notebook, the power system such as a vehicle power system, and high-power illumination system all need a heat management to ensure a stable operating temperature. Therefore, the present disclosure provides a novel heat-dissipating structure that can quickly and efficiently remove heat away from a heat source, such that a system failure caused by a sudden increase in temperature of the component(s).

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

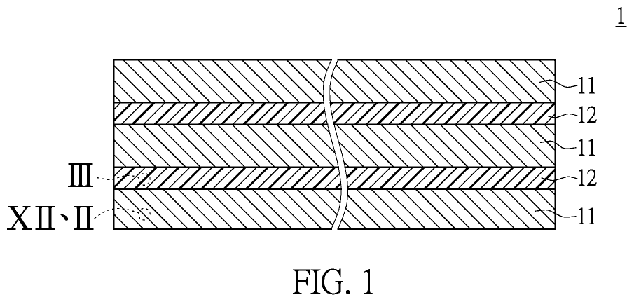

Referring to FIG. 1 to FIG. 4, a first embodiment of the present disclosure provides a heat-dissipating structure 1 which includes a plurality of heat-dissipating layers 11 and at least one heat-buffering layer 12. The heat-dissipating layers 11 are stacked together and the at least one heat-buffering layer 12 is disposed between the heat-dissipating layers 11. Therefore, when the heat-dissipating structure 1 transmits heat, the heat-buffering layer 12 can serve as a heat blocker to allow the transmitted heat to diffuse in an XY direction and then be dissipated over a larger area via the heat-dissipating layers 11.

Although FIG. 1 shows three heat-dissipating layers 11 and two heat-buffering layers 12 and each of the heat-buffering layers 12 is disposed between the two adjacent heat-dissipating layers 11, the number and the positional relationship of the heat-dissipating and heat-buffering layers 11, 12 can be changed depending on thermal conductivity requirements and there is no particular limitation thereto. In the present embodiment, the thickness of the heat-dissipating layer 11 can be from 0.1 μm to 100 μm and the thickness of the heat-buffering layer 12 can be from 0.1 μm to 100 μm, but are not limited thereto.

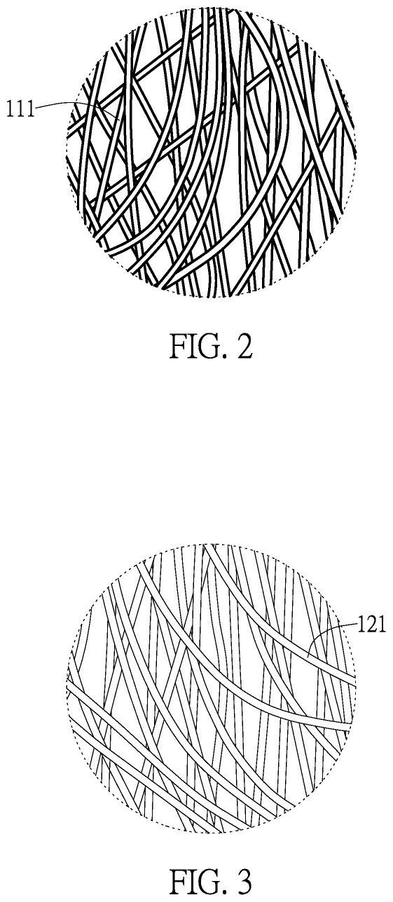

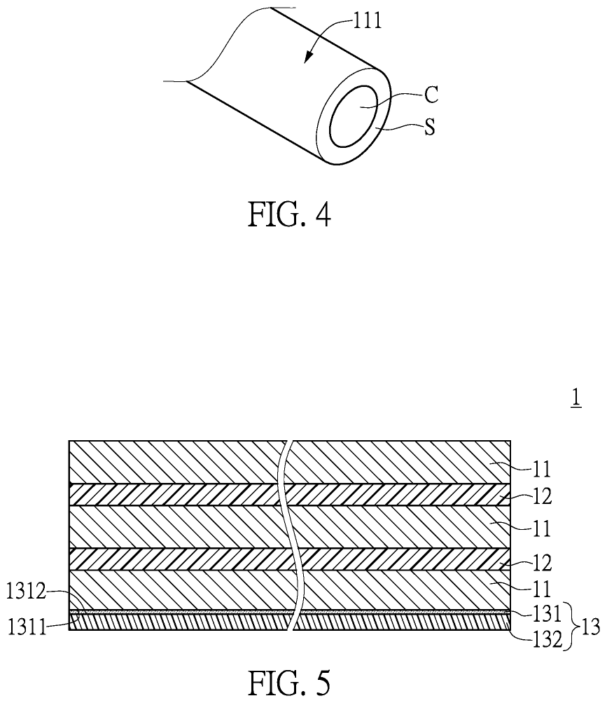

Referring to FIG. 2 in conjunction with FIG. 4, the heat-dissipating layer 11 is formed by a thermally conductive metal coated polymer fiber 111. For example, one or more thermally conductive metal coated polymer fibers 111 may be closely stacked, wound or interlaced in specific directions to form the heat-dissipating layer 11. Specifically, the thermally conductive metal coated polymer fiber 111 includes a polymer core C and a thermally conductive metal sheath S surrounding the polymer core C. The polymer core C has good mechanical strength to serve as a support structure. The thermally conductive metal sheath S has a high surface area to increase the heat absorption and release rates. The outer diameter of the polymer core C can be from 1 nm to 10000 nm and the thickness of the thermally conductive metal sheath S can be from 1 nm to 10000 nm, but are not limited thereto. Although FIG. 4 shows that the thermally conductive metal is in the form of a tubular sheath, in other embodiments, the thermally conductive metal may be in the form of fine particles that are continuously distributed on the surface of the polymer core C.

In the present embodiment, the polymer core C can be made from an acrylic, vinyl, polyester or polyamide polymer or copolymers thereof. The acrylic polymer can be, for example, polymethyl methacrylate (PMMA) or polyacrylonitrile (PAN). The vinyl polymer can be, for example, polystyrene (PS) or polyvinyl acetate (PVAc). The polyester polymer can be, for example, polycarbonate (PC), polyethylene terephthalate (PET), or polybutylene terephthalate (PBT). The polyamide polymer can be, for example, nylon. However, these are merely examples and not meant to limit the instant disclosure. In consideration of mechanical properties and processability, the polymer core C is preferably made from highly crystalline polyethylene terephthalate, polymethyl methacrylate having a low softening temperature or polystyrene having a low softening temperature, but is not limited thereto. In addition, the thermally conductive metal sheath S can be made from gold, silver, copper, platinum or alloys thereof, but is not limited thereto.

Referring to FIG. 3, in the present embodiment, the heat-buffering layer 12 can be formed by an organic polymer fiber 121. For example, one or more pieces of the thermally conductive metal coated polymer fiber 111 may be closely stacked, wound or interlaced in specific directions to form the heat-buffering layer 12. The outer diameter of the organic polymer fiber 121 can be from 1 nm to 10000 nm. The organic polymer fiber 121 can be made from an acrylic, vinyl, polyester or polyamide polymer or copolymers thereof. The specific examples have been described above and will not be reiterated herein. Referring to FIG. 5, the heat-dissipating structure 1 can further includes a carrier 13 for carrying the heat-dissipating layers 11 and the heat-buffering layer 12. The heat-dissipating structure 1 can be transferred to the position of the heat source via the carrier 13. In the present embodiment, the carrier 13 can include an adhesive layer 131 and a temporary substrate 132. The adhesive layer 131 has a first surface 1311 and a second surface 1312 opposite to the first surface 1311. The heat-dissipating layers 11 and the heat-buffering layer 12 can be disposed on the first surface 1311 and the temporary substrate 132 can be disposed on the second surface 1312. Therefore, when the heat-dissipating structure 1 is in use, only the temporary substrate 131 needs to be removed, and the heat-dissipating layers 11 and the heat-buffering layer 12 can be attached to a predetermined position via the adhesive layer 12, so as to dissipate heat from the heat source.

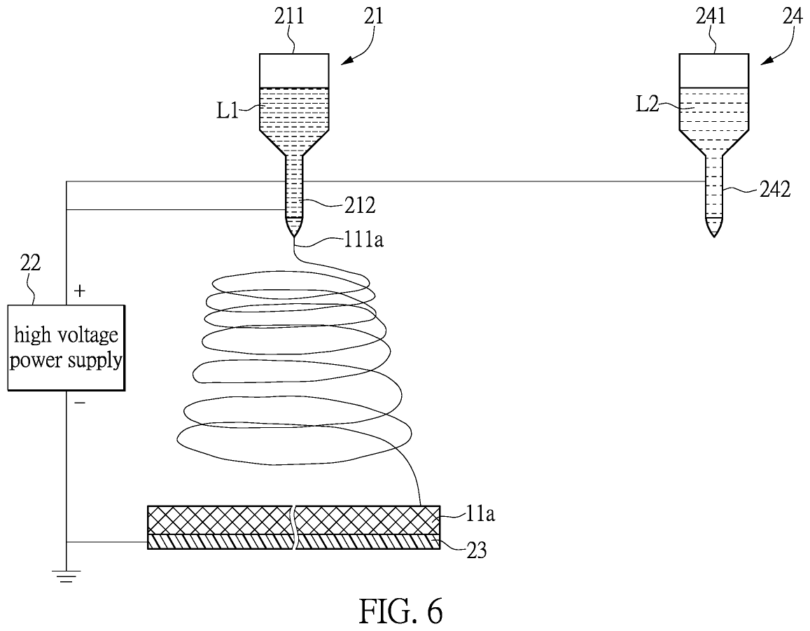

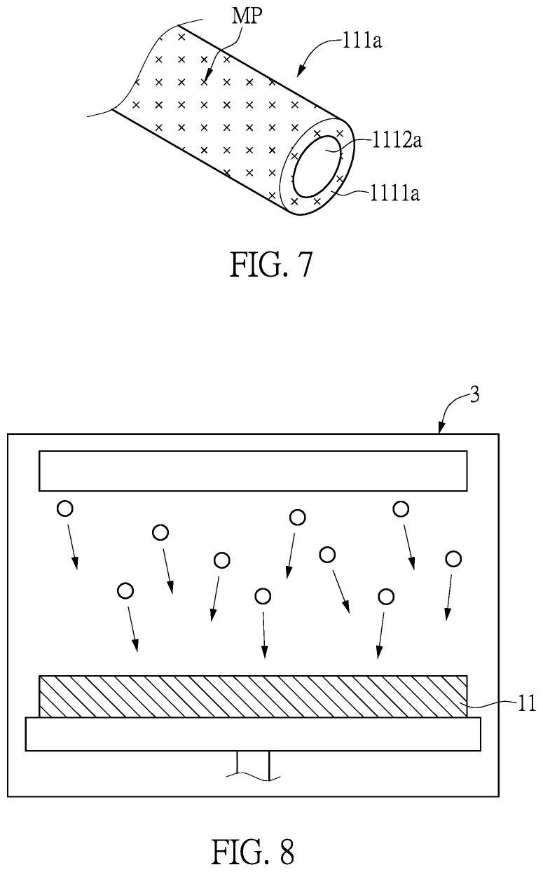

Reference is made to FIG. 6 to FIG. 9. The following will describe a method for manufacturing the heat-dissipating structure 1. Firstly, a composite polymer fiber 111a is provided and formed into a layered structure 11a. The composite polymer fiber 111a includes a core layer 1111a and a surface layer 1112a covering the core layer 1111a. It should be noted that the surface layer 1112a has a thermally conductive metal precursor MP continuously and uniformly distributed in an axial direction therein, as shown in FIG. 7. In the present embodiment, the composite polymer fiber 111a can be provided by an electrospinning device 2. The electrospinning device 2 can include a first fiber spinning unit 21, a high voltage power supply 22 and a collecting board 23. The first spinning unit 21 can include a first liquid storage tank 211 and a first spinning nozzle 212. The first spinning nozzle 212 is in fluid communication with the bottom of the first liquid storage tank 211. The high voltage power supply 22 has positive and negative outputs that are electrically connected to the first spinning nozzle 212 and the collecting board 23, respectively.

More specifically, a first electrospinning liquid L1 can be prepared and placed in the first liquid storage tank 211 of the first spinning unit 21. The first electrospinning liquid L1 mainly includes an organic polymer, a thermally conductive metal precursor and an organic solvent. After that, an electric field with a predetermined intensity is generated between the first spinning unit 21 and the collecting board 23 by the high voltage power supply 22, such that the first electrospinning liquid L1 is ejected from the first nozzle 212 and is formed into a composite polymer fiber 111a that is deposited on the collecting board 23. It should be noted that, if the heat-dissipating structure 1 includes a carrier 13, the carrier 13 can be placed on the collecting plate 23 before the composite polymer fiber 111a is provided.

Although FIG. 7 shows that the composite polymer fiber 111a is formed by electrospinning, in other embodiments, the composite polymer fiber 111a can be formed by other processes such as flash spinning, electrospray, melt blown and electrostatic melt blown processes.

In the present embodiment, the organic polymer is the same as the material of the polymer core C. The thermally conductive metal precursor MP is a precursor of the metal component of the thermally conductive metal sheath S, which may be a metal salt, metal halide or metal organic complex, but is not limited thereto. The organic solvent may be methanol or butanone, but is not limited thereto. If the metal component is gold, the precursor thereof may be exemplified by gold trichloride and tetrachloroauric acid. If the metal component is silver, the precursor thereof may be exemplified by silver trifluoroacetate, silver acetate, silver nitrate, silver chloride and silver iodide. If the metal component is copper, the precursor thereof may be exemplified by copper acetate, copper hydroxide, copper nitrate, copper sulfate, copper chloride and copper phthalocyanine. If the metal component is platinum, the precursor thereof may be exemplified by Sodium hexafluoroplatinate. However, these are merely examples and not meant to limit the instant disclosure.

After the formation of the layered structure 11a based on the composite polymer fiber 111a, the thermally conductive metal precursor MP of the composite polymer fiber 111a is reduced to thermally conductive metal. Accordingly, the layered structure 11a is formed into a heat-dissipating layer 11. In the present embodiment, the thermally conductive metal precursor MP of the composite polymer fiber 111a can be reduced by a plasma treating device 3, so as to form the composite polymer fiber 111a into a thermally conductive metal coated polymer fiber. More specifically, the plasma treating device 3 can perform a low pressure, high pressure or atmospheric plasma treatment and the treatment time can be from 1 second to 300 seconds. The plasma treatment can use an inert gas, air, oxygen or hydrogen plasma and be performed under in an inert gas atmosphere (e.g., argon atmosphere), nitrogen atmosphere or reducing atmosphere. The reducing atmosphere may include a mixture of hydrogen gas and nitrogen or an inert gas (e.g., argon gas), wherein the hydrogen content may be from 2% to 8%, preferably 5%. However, the operation conditions of the plasma treatment can be adjusted according to actual requirements and there is no limitation thereto. During the plasma treatment, when the thermally conductive metal formed by reduction gradually accumulates on the outer surface of the polymer inner core C to form a continuous thermally conductive metal sheath S, the polymer core C would not suffer plasma bombardment.

Although FIG. 8 shows that the thermally conductive metal precursor MP of the composite polymer fiber 111a is reduced during the plasma treatment, in other embodiments, the thermally conductive metal precursor MP can be reduced by other treatments, for example, using a strong base such as sodium hydroxide.

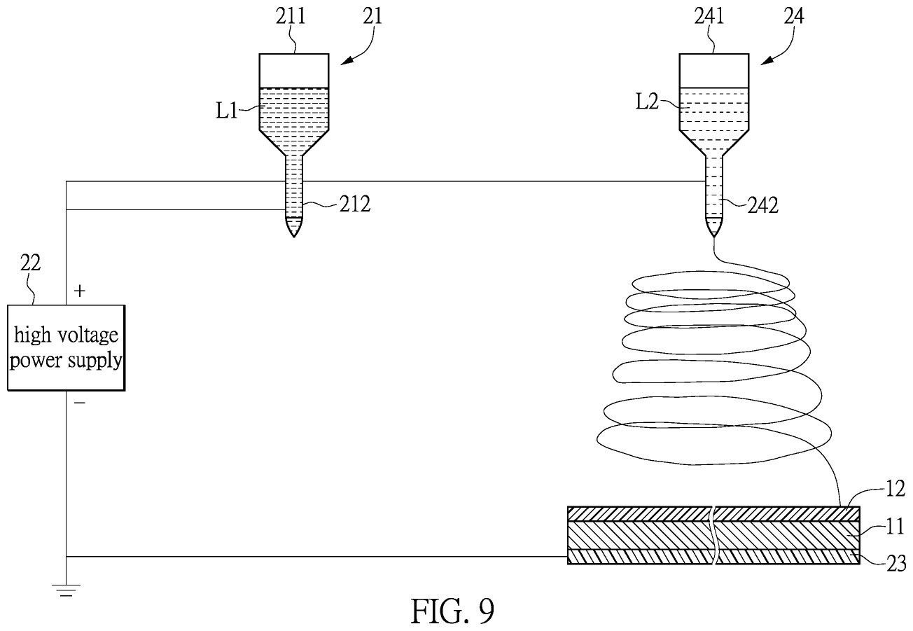

After the formation of the heat-dissipating layer 11, an organic polymer fiber 121 is provided on the heat-dissipating layer 11 and formed into heat-buffering layer 1. In the present embodiment, the organic polymer fiber 121 can be provided by the electrospinning device 2 as shown in FIG. 9. The electrospinning device 2 can further include a second fiber spinning unit 24. The second fiber spinning unit 24 can include a second liquid storage tank 241 and a second spinning nozzle 242 in fluid communication with the bottom of the second liquid storage tank 241. The second spinning nozzle 242 is also electrically connected to the positive output of the high voltage power supply 22.

More specifically, a second electrospinning liquid L2 can be prepared and placed in the second liquid storage tank 241 of the second spinning unit 24. The second electrospinning liquid L2 includes an organic polymer and an organic solvent. After that, an electric field with a predetermined intensity is generated between the second spinning unit 24 and the collecting board 23 by the high voltage power supply 22, such that the second electrospinning liquid L2 is ejected from the second nozzle 242 and is formed into an organic polymer fiber 121 that is deposited on the heat-dissipating layer 11. In the present embodiment, the organic polymer is the organic polymer is the same as the material of the organic polymer fiber 121 and the organic solvent may be methanol or butanone, but are not limited thereto.

Although FIG. 9 shows that the organic polymer fiber 121 is formed by electrospinning, in other embodiments, the organic polymer fiber 121 can be formed by other processes such as flash spinning, electrospray, melt blown and electrostatic melt blown processes.

It should be noted that, the aforesaid step of forming the heat-dissipating layer 11 can be repeated more than once according to heat conduction requirements. When the plurality of heat-buffering layers 12 are needed, the above step of forming the heat-buffering layers 12 can be repeated more than once.

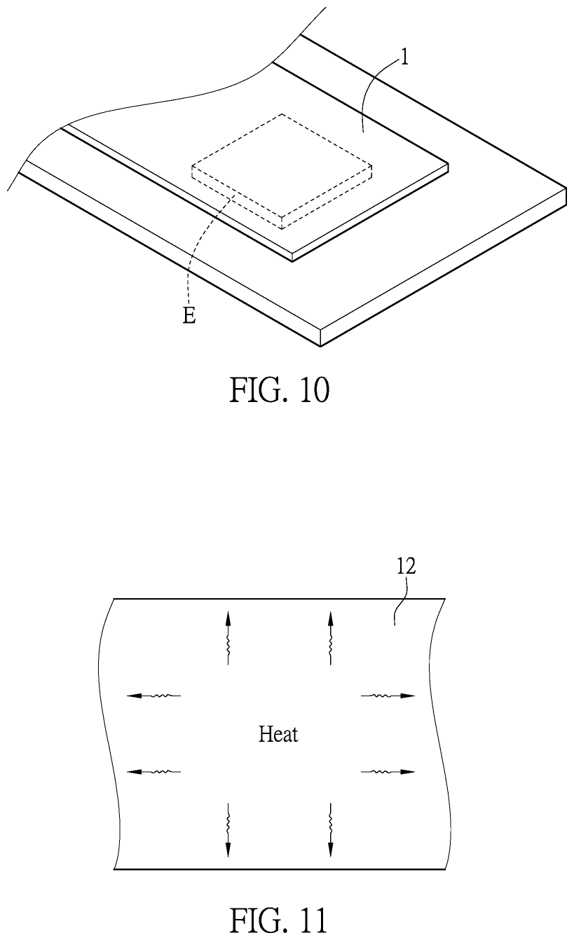

Reference is made to FIG. 10 and FIG. 11. The heat-dissipating structure 1 can remove heat from an electronic product which easily generates a large amount of heat. More specifically, the heat-dissipating structure 1 can directly contact an electronic component E such that the heat generated from the electronic component E can be transmitted in the horizontal direction (i.e., X-Y direction) via the heat-buffering layer(s) 12 and dissipated over a large area via the heat-dissipating layers 11.

### Second Embodiment

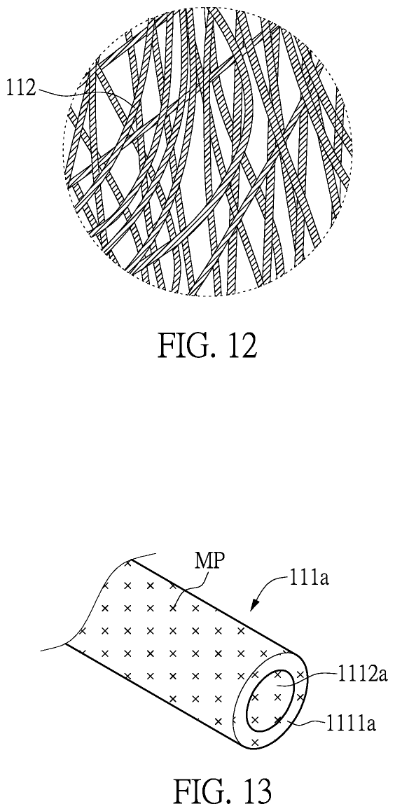

Referring to FIG. 1 in conjunction with FIG. 12, a second embodiment of the present disclosure provides a heat-dissipating structure 1 which includes a plurality of heat-dissipating layers 11 and at least one heat-buffering layer 12. The heat-dissipating layers 11 are stacked together and the at least one heat-buffering layer 12 is disposed between the heat-dissipating layers 11. The main difference of the second embodiment from the first embodiment is that heat-dissipating layer 11 is formed by a thermally conductive metal fiber 112. For example, one or more thermally conductive metal fibers 112 may be closely stacked, wound or interlaced in specific directions to form the heat-dissipating layer 11. The outer diameter of the thermally conductive metal fiber 112 can be from 1 nm to 10000 nm. The thermally conductive metal fiber 112 can be made from gold, silver, copper, platinum or alloys thereof, but is not limited thereto.

Referring to FIG. 6 and FIG. 7 in conjunction with FIG. 13, in the present embodiment, the method for forming the heat-dissipating layer 11 firstly provides a composite polymer fiber 111a and forms the composite polymer fiber 111a into a layered structure 11a. The composite polymer fiber 111a includes a core layer 1111a and a surface layer 1112a covering the core layer 1111a. It should be noted that the core layer 1111a and the surface layer 1112a both have a thermally conductive metal precursor MP continuously and uniformly distributed in an axial direction therein, as shown in FIG. 13. The thermally conductive metal precursor MP is the same as the material of the thermally conductive metal fiber 112. After that, the thermally conductive metal precursor MP of the composite polymer fiber 111a is reduced to thermally conductive metal, so as to form the layered structure 11a into a heat-dissipating layer 11. The technical details of providing the composite polymer fiber 111a and reducing the thermally conductive metal precursor MP can refer to the first embodiment, and will not be reiterated herein.

### Third Embodiment

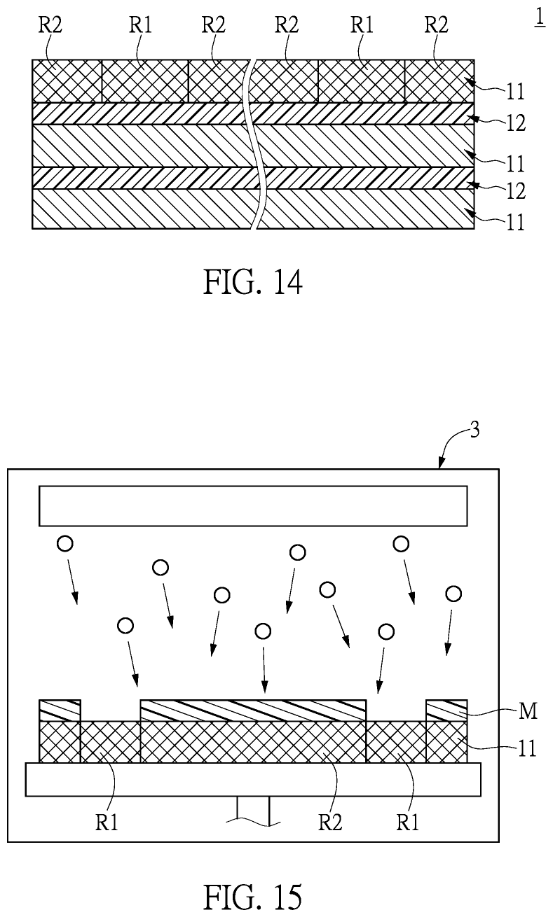

Referring to FIG. 14 and FIG. 15, a third embodiment of the present disclosure provides a heat-dissipating structure 1 which includes a plurality of heat-dissipating layers 11 and at least one heat-buffering layer 12. The heat-dissipating layers 11 are stacked together and the at least one heat-buffering layer 12 is disposed between the heat-dissipating layers 11. The main difference of the third embodiment from the above embodiments is that one of the heat-dissipating layers 11 has at least one thermally conductive region R1 and a thermally non-conductive region R2 to meet special applications.

In the present embodiment, the method for forming the heat-dissipating layer 11 firstly provides a composite polymer fiber 111a and forms the composite polymer fiber 111a into a layered structure 11a. Next, a patterned mask M is formed on the layered structure 11a to expose a predetermined portion of the layered structure 11a. After that, a plasma treatment is performed on the predetermined portion of the layered structure 11a via the patterned mask M to reduce the thermally conductive metal precursor MP of the composite polymer fiber 111a of the predetermined portion to thermally conductive metal, so as to form the thermally conductive region R1. The other portion of the layered structure 11a, which is not treated with plasmas, forms the thermally non-conductive region R2.

Although FIG. 15 shows that the uppermost heat-dissipating layer 11 has the thermally conductive and thermally non-conductive regions R1, R2, in other embodiments, the heat-dissipating layer 11 at another location can also have the thermally conductive and thermally non-conductive regions R1, R2.

One of the advantages of the present disclosure is that the heat-dissipating structure of the present disclosure, in which the at least one heat-buffering layer disposed between the plurality of heat-dissipating layers and each of the heat-dissipating layers is formed by a thermally conductive metal coated polymer fiber or thermally conductive metal fiber, can remove heat from an electronic component which easily generates a large amount of heat. In use, the heat generated from the electronic component E can be transmitted in the horizontal direction (i.e., X-Y direction) via the heat-buffering layer(s) 12 and dissipated over a large area via the heat-dissipating layers 11.

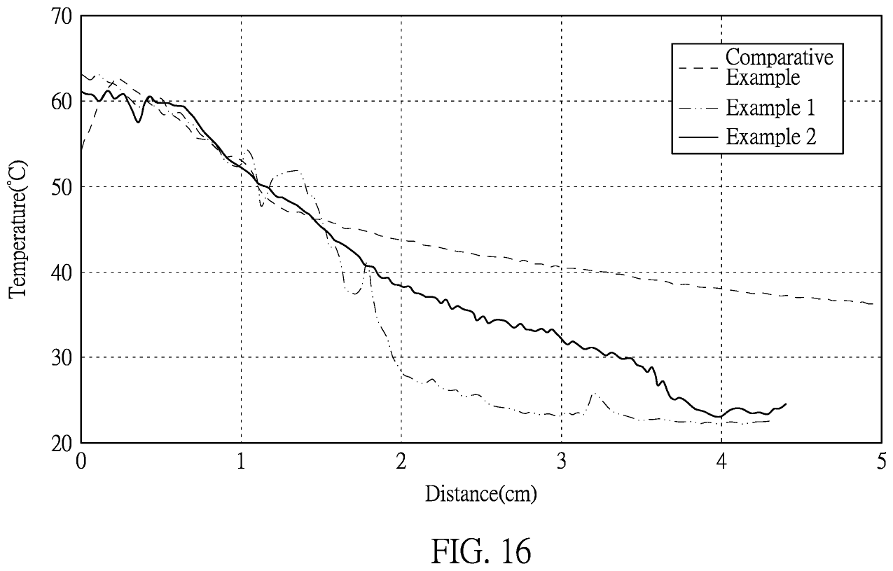

Reference is made to FIG. 16, which shows a heat transmission test between the heat-dissipating structures of Comparative Example and Examples 1 and 2. The heat transmission test is to directly contact one end of the heat-dissipating structure with a heated plate of 185° C. and subsequently use a thermographic camera to estimate the temperature curve showing cooled temperatures at corresponding distances. The heat-dissipating structure of Comparative Example 1 is a commercial graphite sheet. The heat-dissipating structure of Example 1 only includes a heat-dissipating layer and the heat-dissipating structure of Example 2 includes a heat-dissipating layer and a heat-buffering layer. It can be observed from FIG. 16 that the heat-dissipating structures of Examples 1 and 2 have better cooling effect than the heat-dissipating structure of Comparative Example 1, which have a temperature difference of about 10° C. at a distance of 2 cm away from the heat source. Furthermore, the heat-dissipating structures of Examples 1 and 2 have a temperature that is near the room temperature at a distance of 4 cm away from the heat source. It is analyzed that the thermally conductive metal coated polymer fiber is provided with a high surface area such that it is capable of performing a heat exchange with air.

In addition, a commercial graphite sheet, a high-density heat-dissipating layer formed using a deposition time of 40 minutes and a low-density heat-dissipating layer formed using a deposition time of 10 minutes are respectively contacted with a SUS316 stainless steel substrate via a copper block. Subsequently, a thermographic camera is used to observe the cooling effect at different temperatures from a top direction. The result obtained is shown in Table 1.

TABLE 1

| | The highest temperature on heat-dissipating structure | | |
|---|---|---|---|
| Temperature | commercial | high-density heat- | low-density heat- |
| of substrate | graphite sheet | dissipating layer | dissipating layer |
| 93.5° C. | 78.2° C. | 70.1° C. | 84.1° C. |
| 80.7° C. | 67.9° C. | 60.3° C. | 69.7° C. |
| 62.8° C. | 50.1° C. | 44.1° C. | 59.8° C. |
| 50.3° C. | 42.3° C. | 38.8° C. | 48.5° C. |
| 43.2° C. | 37.0° C. | 30.9° C. | 41.1° C. |
| 34.5° C. | 26.3° C. | 25.5° C. | 30.3° C. |
| 26.8° C. | 26.1° C. | 24.8° C. | 25.9° C. |

It can be observed from Table 1 that the commercial graphite sheet, the high-density heat-dissipating layer and the low-density heat-dissipating layer have similar cooling effects. The high-density heat-dissipating layer has an improved heat-dissipating performance than the commercial graphite sheet. Furthermore, the thermally conductive metal coated polymer fiber includes a polymer core and a thermally conductive metal sheath surrounding the polymer core. The polymer core has good mechanical strength to serve as a support structure and the thermally conductive metal sheath has a high surface area to increase the heat absorption and release rates. In addition, the heat-buffering layer is formed by an organic polymer fiber. Therefore, the heat-dissipating structure can balance light weight, structural strength and heat-dissipating ability to meet the design requirements of the light-weight thin electronic devices.

The present disclosure further provides a method for manufacturing the heat-dissipating structure, which can use a recycled metal waste liquid, is suitable for industrial mass production and can reduce resource consumption and environmental pollution.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a heat-dissipating structure, comprising:
(A) providing a composite polymer fiber and forming the composite polymer fiber into a layered structure, wherein the composite polymer fiber has a thermally conductive metal precursor uniformly distributed thereon;
(B) reducing the thermally conductive metal precursor to a thermally conductive metal so as to form the layered structure into a heat-dissipating layer;
(C) providing an organic polymer fiber and forming the organic polymer fiber into a heat-buffering layer; and
(D) repeating the steps (A) and (B) or the steps (A) to (C).

2. The method according to claim 1, wherein the composite polymer fiber includes a core layer and a surface layer covering the core layer and the thermally conductive metal precursor are uniformly distributed in the surface layer, wherein the step (B) includes treating the layered structure with plasmas such that the composite polymer fiber in the layered structure is formed into a thermally conductive metal coated polymer fiber, and wherein the thermally conductive metal coated polymer fiber includes a polymer core and a thermally conductive metal sheath surrounding the polymer core.

3. The method according to claim 1, wherein the composite polymer fiber includes a core layer and a surface layer covering the core layer and the effect amount of the thermally conductive metal precursor are uniformly distributed in the core layer and the surface layer, and wherein the step (B) includes treating the layered structure with plasmas such that the composite polymer fiber in the layered structure is formed into a thermally conductive metal fiber.

4. The method according to claim 1, wherein the step (A) includes providing the composite polymer fiber by electrospinning and the step (C) includes providing the organic polymer fiber by electrospinning.

5. A heat-dissipating structure, comprising:
a plurality of heat-dissipating layers stacked together, wherein each of the heat-dissipating layers is formed by a thermally conductive metal coated polymer fiber; and
at least one heat-buffering layer disposed between the heat-dissipating layers.

6. The heat-dissipating structure according to claim 5, wherein the thermally conductive metal coated polymer fiber includes a polymer core and a thermally conductive metal sheath surrounding the polymer core.

7. The heat-dissipating structure according to claim 6, wherein the polymer core has an outer diameter between 1 nm and 10000 nm, and the polymer core is made from highly crystalline polyethylene terephthalate (PET), polymethyl methacrylate (PMMA) having a low softening temperature or polystyrene (PS) having a low softening temperature.

8. The heat-dissipating structure according to claim 6, wherein the thermally conductive metal sheath has a thickness between 1 nm and 10000 nm, and the thermally conductive metal sheath is made from gold, silver, copper, platinum or alloys thereof.

9. The heat-dissipating structure according to claim 5, wherein one of the heat-dissipating layers has at least one thermally conductive region and a thermally non-conductive region, and the at least one thermally conductive region is made from gold, silver, copper, platinum or alloys thereof.

10. The heat-dissipating structure according to claim 5, wherein the at least one heat-buffering layer is formed by an organic polymer fiber, and the organic polymer fiber is made from an acrylic, vinyl, polyester or polyamide polymer.

11. The heat-dissipating structure according to claim 5, wherein the at least one heat-buffering layer is a plastic layer, and the plastic layer is made from an acrylic, vinyl, polyester or polyamide polymer.

12. The heat-dissipating structure according to claim 5, further comprising a carrier for carrying the heat-dissipating layers and the at least one heat-buffering layer.

13. The heat-dissipating structure according to claim 5, wherein the heat-dissipating layer has a thickness between 0.1 μm and 100 μm and the heat-buffering layer has a thickness between 0.1 μm and 100 μm.

14. A heat-dissipating structure, comprising:
a plurality of heat-dissipating layers stacked together, wherein each of the heat-dissipating layers is formed by a thermally conductive metal fiber; and
at least one heat-buffering layer disposed between the heat-dissipating layers.

15. The heat-dissipating structure according to claim 14, wherein the thermally conductive metal fiber is made from gold, silver, copper, platinum or alloys thereof.

16. The heat-dissipating structure according to claim 14, wherein the thermally conductive metal fiber has an outer diameter between 1 nm and 10000 nm.

17. The heat-dissipating structure according to claim 14, wherein the at least one heat-buffering layer is formed by an organic polymer fiber, and the organic polymer fiber is made from an acrylic, vinyl, polyester or polyamide polymer.

18. The heat-dissipating structure according to claim 14, wherein the at least one heat-buffering layer is a plastic layer, and the plastic layer is made from an acrylic, vinyl, polyester or polyamide polymer.

19. The heat-dissipating structure according to claim 14, further comprising a carrier for carrying the heat-dissipating layers and the at least one heat-buffering layer.

20. The heat-dissipating structure according to claim 14, wherein the heat-dissipating layer has a thickness between 0.1 μm and 100 μm and the heat-buffering layer has a thickness between 0.1 μm and 100 μm.
